(19) United States
(12) Patent Application Publication
(10) Pub. No.: US 2012/0314359 A1
(43) Pub. Date: Dec. 13, 2012

(54) FOLDABLE ELECTRONIC DEVICE

(75) Inventor: YI-HUNG HSIEH, Tu-Cheng (TW)

(73) Assignee: HON HAI PRECISION INDUSTRY CO., LTD., Tu-Cheng (TW)

(21) Appl. No.: 13/195,033

(22) Filed: Aug. 1, 2011

(30) Foreign Application Priority Data
Jun. 7, 2011 (TW) 100119746

(51) Int. Cl. H05K 7/00

(52) U.S. Cl. 361/679.12; 361/679.01

(57) ABSTRACT

A foldable electronic device is provided. The foldable electronic device includes a first part, a second part, and a third part. The first part and the second part are connected with a first hinge, the second part and the third part are connected with a second hinge, the first part and the second part are capable of rotating 0-α degrees relative to each other around the first hinge. The second part and the third part are capable of rotating 0-α degrees relative to each other around the second hinge, wherein a is equal to or greater than 180 degree, the first part comprises a screen, the third part comprises a keyboard.

### BACKGROUND

1. Technical Field

The present disclosure relates to a foldable electronic device.

2. Description of Related Art

In order to save space, some electronic devices, such as tablet computers, have a touch screen for input, and there is no physical keyboard. When using the electronic device with the touch screen, a virtual keyboard is displayed on the screen for input. However, the virtual keyboard reduces the display space. Furthermore, the operation of the virtual keyboard is not convenient, and it is easy to make mistakes.

### BRIEF DESCRIPTION OF THE DRAWINGS

The components of the drawings are not necessarily drawn to scale, the emphasis instead being placed upon clearly illustrating the principles of the present disclosure. Moreover, in the drawings, like reference numerals designate corresponding parts throughout several views.

FIGS. 1 and 2 are isometric views of a foldable electronic device in accordance with an exemplary embodiment, showing two different aspects of the device being unfolded.

FIG. 3 is an isometric view of the foldable electronic device of FIG. 1 when a keyboard of the electronic device is used.

FIG. 4 is an isometric view of the foldable electronic device of FIG. 1 when the keyboard of the electronic device is not used, and a screen of the electronic device is used as a tablet.

FIG. 5 is an isometric view of the foldable electronic device of FIG. 1 when the electronic device is folded.

### DETAILED DESCRIPTION

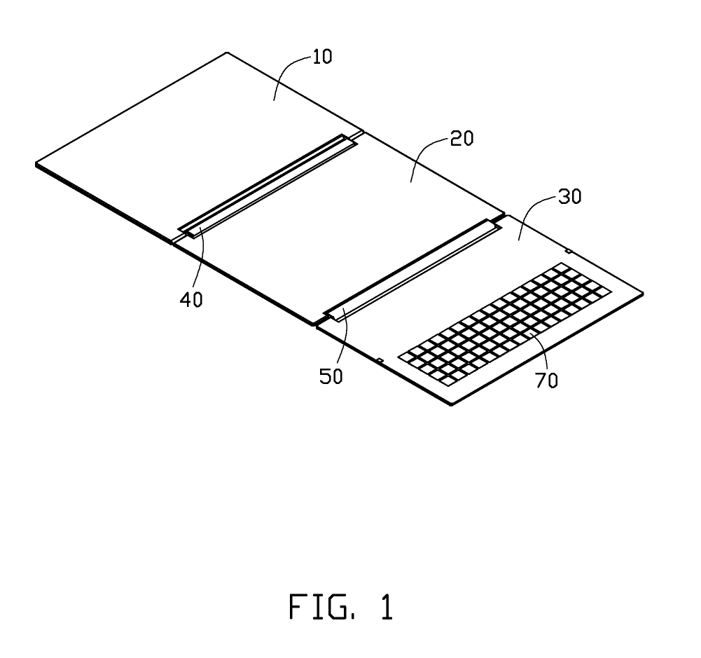

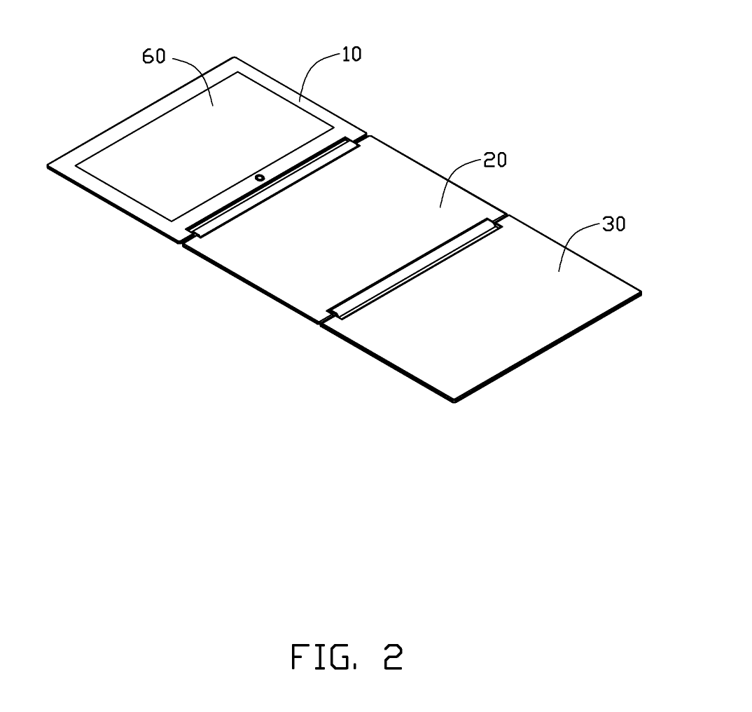

Referring to FIGS. 1-2, a foldable electronic device 1 includes a first part 10, a second part 20, and a third part 30. The first part 10 and the second part 20 are connected with a first hinge 40. The second part 20 and the third part 30 are connected with a second hinge 50. The first part 10 and the second part 20 is capable of rotating between 0-α degree relative to each other around the first hinge 40. The second part 20 and the third part 30 are capable of rotating between 0-α degree relative to each other around the second hinge 50, wherein α is equal to or greater than 180 degrees. In the present embodiment, α is equal to 180 degrees.

The first part 10 includes a screen 60. The third part 30 includes a keyboard 70. The other components, such as a data storage, a processing unit, a sound card, and a video card, of the electronic device 1 can be arranged in the first part 10, the second part 20, and/or the third part 30. The components that are arranged in different parts of the electronic device 1 can be electrically connected with a wire passing through the first hinge 40 and/or the second hinge 50.

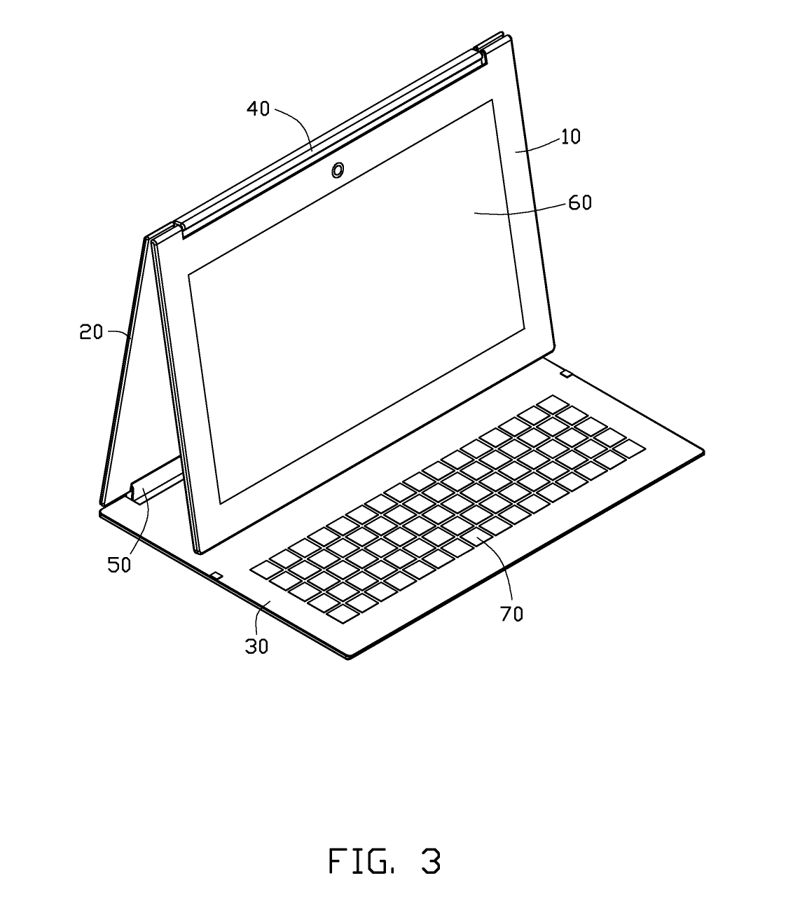

Referring to FIG. 3, when the keyboard 70 of the electronic device 1 is used, the second part 20 rotates around the first hinge 40 to form an angle with the first part 10. The third part 30 rotates around the second hinge 50 to form an angle with a second part 20. The first part 10 is supported on a side with the keyboard 70 of the third part 30, and the side with the screen 60 of the first part 10 faces the user. Thereby, the user can use the keyboard 70 of the third part 20 to control the content displayed in the screen 60 of the first part 10.

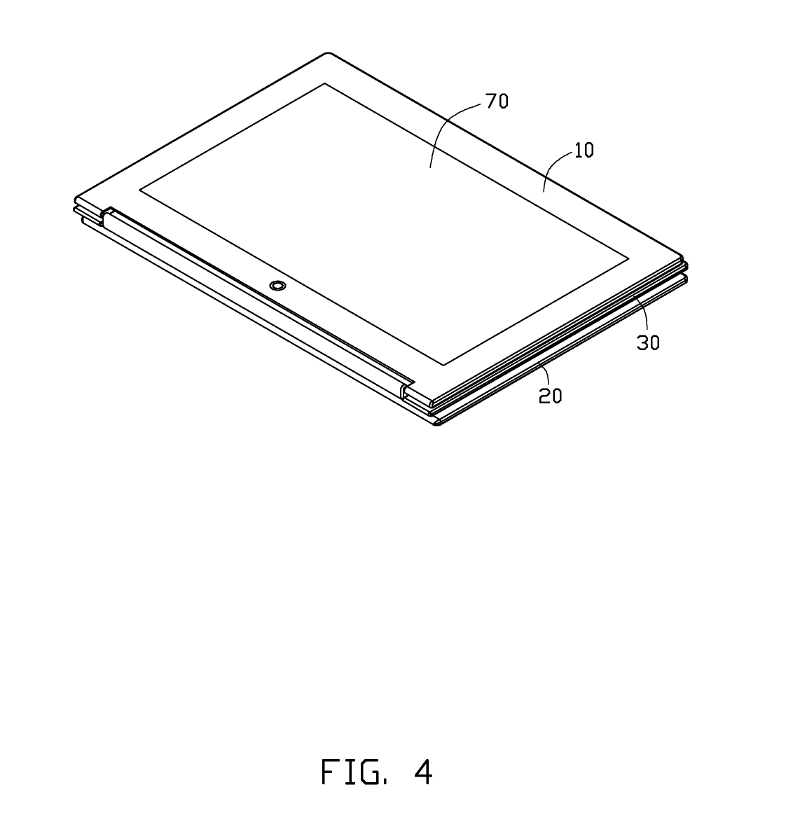

When the screen 60 needs to be used and the keyboard 70 does not need to be used, as shown in FIG. 4, the first part 10, the second part 20, and the third part 30 are folded to make the first part 10 overlap over the second part 20, and the second part 20 overlap over the third part 30, and thus the screen 60 is exposed.

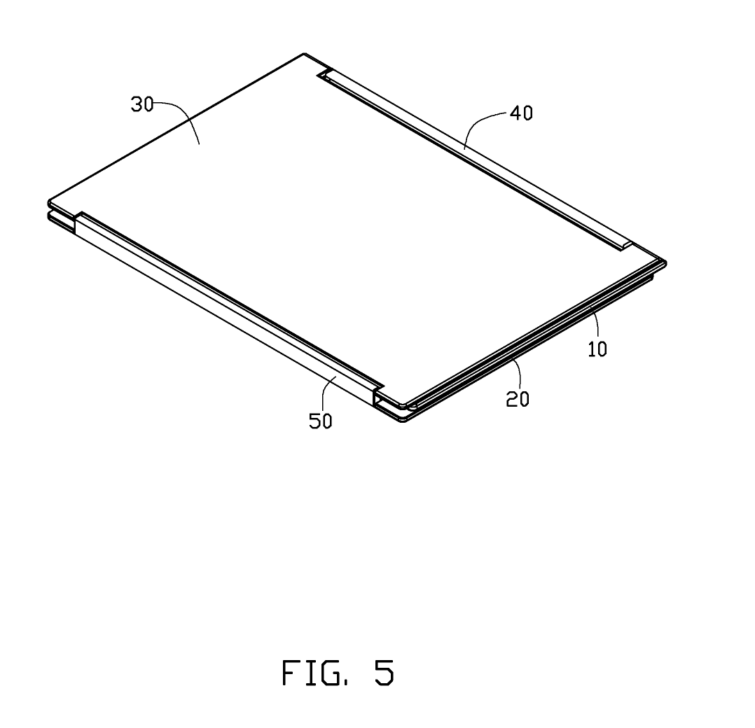

When the electronic device 1 needs to be closed, as shown in FIG. 5. The first part 10, the second part 20, and the third part 30 are folded to make the third part 30 overlap over the first part 10 and the first part 10 overlap over the second part 20, and thus the screen 60 in the first part 10 is protected from being damaged.

In the present embodiment, the electronic device 1 is a tablet computer.

Although, the present disclosure has been specifically described on the basis of preferred embodiments, the disclosure is not to be construed as being limited thereto. Various changes or modifications may be made to the embodiment without departing from the scope and spirit of the disclosure.

What is claimed is:

1. A foldable electronic device comprising:
a first part;
a second part; and
a third part;
wherein the first part and the second part are connected with a first hinge, the second part and the third part are connected with a second hinge, the first part and the second part are capable of rotating 0-α degrees relative to each other around the first hinge, the second part and the third part are capable of rotating 0-α degrees around the second hinge relative to each other, wherein α is equal to or greater than 180 degrees, the first part comprises a screen, the third part comprises a keyboard.

2. The foldable electronic device as described in claim 1, wherein components of the electronic device are arranged in the first part, the second part, and/or the third part, the components arranged in different parts of the electronic device are electrically connected through a wire passing through the first hinge and/or the second hinge.

3. The foldable electronic device as described in claim 1, wherein the electronic device is a tablet computer.
